(19) United States
(12) Patent Application Publication
(10) Pub. No.: US 2005/0127954 A1
(43) Pub. Date: Jun. 16, 2005

(54) Signal processing apparatus

(76) Inventor: Hirofumi Hari, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 10/975,040

(22) Filed: Oct. 26, 2004

(30) Foreign Application Priority Data
Oct. 30, 2003 (JP) 2003-373384

(51) Int. Cl. H03K 3/00

(52) U.S. Cl. 327/99

(57) ABSTRACT

In digital mixers and other signal processing apparatus, visual confirmation of signal transmission paths is difficult. A signal processing apparatus is provided with digital signal processing and control means 3, including a DSP and CPU, between input means 1a through 1f and output means 2a and 2b. The signal processing and control means 3 is connected to operation means 4, including a plurality of operation buttons, and to display means 5, including a plurality of display devices. The signal processing and control means 3 includes a plurality of mixer means 26a through 261 and display control means 5a. A plurality of operation buttons are used to form a plurality of signal transmission paths. A plurality of display devices provided in correspondence with a plurality of operation buttons, have a function to display operation of the operation buttons, and in addition are also used to display signal transmission paths. A plurality of display devices associated with a signal transmission path are lighted in sequence along the signal transmission path.

### BACKGROUND OF THE INVENTION

1. Field of the Invention

This invention relates to a signal processing apparatus which transmits signals of input means to output means via, for example, digital mixer signal processing means.

2. Description of the Related Art

The replacement of an analog mixer with a digital mixer between input means and output means is known, as in for example Japanese Published Patent Application No. H11-215078 (patent reference 1) and Japanese Published Patent Application No. 2003-168962 (patent reference 2).

In a digital mixer, a plurality of audio input signals are each converted into digital signals, and addition and other processing of the plurality of digital audio signals are executed in a DSP (digital signal processor); and the processed digital signals are then converted into analog signals to be output. This signal processing is performed by the software of the DSP, so that mixing and other processing through complex signal paths, which are difficult to realize in a conventional analog mixer, can easily be executed.

However, when in a digital mixer or a similar signal processing apparatus the paths from the input terminal to the output terminal have numerous stages or are complex, the operator cannot readily recognize the manner in which the signal paths are set. In patent reference 2, light-emitting elements are positioned in proximity to operation buttons to form signal paths, and the light-emitting elements emit light in response to operation of the operation buttons, so that the ability to recognize the signal transmission path is improved. However, the light-emitting elements in patent reference 2 indicate operation of the operation buttons, and do not indicate the signal transmission path or flow of signals.

Hence there is the problem that, in a digital mixer and similar signal processing apparatuses, recognition of the signal transmission path is difficult.

### SUMMARY OF THE INVENTION

The present invention to resolve the above problem is explained below, referring to the symbols in drawings illustrating embodiments of the invention. However, it should be noted that reference symbols in each of the claims, as well as in the following explanation of the invention, are intended to promote understanding of the invention, and do not limit the invention.

This invention relates to a signal processing apparatus, including:
at least one input means (1a) to input electrical signals;
at least one output means (2a) to output electrical signals;
signal processing and control means (3), connected between the above input means and the above output means, and having a control function of selectively forming a plurality of signal transmission paths connected between the above input means and the above output means, and a function of performing arbitrary signal processing of signals with respect to the above plurality of signal transmission paths;
input selection means (40a), capable of manual operation, for selectively applying, to the above signal processing and control means (3), signals to order the selective use by the above signal processing and control means of the output signals of the above input means (1a);
output selection means (70), capable of manual operation, for selectively applying, to the above signal processing and control means, signals to order that output signals of the above signal processing and control means be sent to the above output means (2a);
a plurality of signal transmission path selection means (46a through 461, and/or 51a through 511), capable of manual operation, for selectively ordering the formation of the above plurality of signal transmission paths;
an input display device (41a), disposed in a predetermined positional relationship with the above input selection means (40a);
an output display device (71), disposed in a predetermined positional relationship with the above output selection means (70);
a plurality of signal transmission path selection display devices (47a through 471, and/or 52a through 521), disposed in predetermined positional relationships with the above plurality of signal transmission path selection means (46a through 461, and/or 51a through 511); and
display control means (5a), connected to the above input selection means (40a), the above output selection means (70), the above plurality of signal transmission path selection means (46a through 461 and/or 51a through 511), the above input display device (41a), the above output display device (71), and the above plurality of signal transmission path selection display devices (47a through 471 and/or 52a through 521) which sequentially controls the display states, with time differences, of:
one or a plurality selected from among the above input display device (41a) and the above plurality of signal transmission path selection display devices (47a through 471 and/or 52a through 521), and the above output display device (71), each of which has a predetermined relation with the above selected signal transmission path,
in response to the operation of one or a plurality among the above input selection means (40a), the above output selection means (70), and the above plurality of signal transmission path selection means (46a through 461 and/or 51a through 511), having a predetermined relationship with the above selected signal transmission path, or to the operation of separately provided signal transmission path display instruction means (100)
in a state in which at least one signal transmission path selected from among the above plurality of signal transmission paths is formed.

As indicated in claim 2, it is desirable that the signal processing apparatus further includes display control means for controlling the display states of the above input display device (41a), the above output display device (71), and the above plurality of signal transmission path selection display devices (47a through 471 and/or 52a through 521), in response to operation of the above input selection means (40a), the above output selection means (70), and the above plurality of signal transmission path selection means (46a through 461 and/or 51a through 511) at the time of selective formation of the above signal transmission paths.

Further, as indicated in claim 3, it is desirable that the above input display device (41a) be disposed in proximity to the above input selection means (40a); that the above output display device (71) be disposed in proximity to the above output selection means (70); and that the above plurality of signal transmission path selection display devices (47a through 471 and/or 52a through 521) be disposed in proximity to the above plurality of respective signal transmission path selection means (46a through 461 and/or 53a through 531).

Further, as indicated in claim 4, it is desirable that the above input selection means be an input selection switch (42a) having a manual operation unit (40a); that the above output selection means be an output selection switch (42a) having a manual operation unit (70); that the above plurality of signal transmission path selection means be a plurality of signal transmission path selection switches (48a through 481 and/or 53a through 531) each having a manual operation unit (46a through 461 and/or 51a through 511); that the above input display device (41a) be integrally formed with the operation unit (40a) of the above input selection switch; that the above output display device (71) be integrally formed with the operation unit (70) of the above output selection switch; and that the above plurality of signal transmission path selection display devices (47a through 471 and/or 52a through 521) be integrally formed with the operation units (46a through 461 and/or 51a through 511) of the above plurality of respective signal transmission path selection switches.

Further, as indicated in claim 5, it is desirable that the signal processing apparatus further includes a plurality of interruption instruction means (56a through 561) for giving instruction of interruption of signal transmission by the above respective signal transmission paths; a plurality of interruption display devices (57a through 571) provided corresponding to the above plurality of interruption instruction means (56a through 561); and, means for lighting or flashing display control of the above interruption display devices relating to interrupted signal transmission paths when, in a state in which the above signal transmission path is selectively formed and the above interruption instruction means (56a through 561) belonging to the signal transmission path is operated to be interrupted, orders are given to the above input display device (41a), to one or a plurality selected from among the above plurality of signal transmission path selection display devices (47a through 471 and/or 52a through 521), and to the above output display device (71), with time differences therebetween, to sequentially control display states.

Further, as indicated in claim 6, it is desirable that the above input means (1a) output digital signals, that the above signal processing control means include a CPU, and that the above CPU have control functions to selectively form a plurality of signal transmission paths and moreover that the above CPU also be used by the above display control means (5a).

Further, as indicated in claim 7, it is desirable that the above signal processing control means includes:
a bus (13);
a plurality of memory means (25a through 251), selectively connected to the above input means (1a) in response to operation of the above input selection means (40a);
a plurality of signal processing means for performing predetermined signal processing of the output of the above plurality of memory means (25a through 251) in response to operation of the above signal transmission path selection means;
a plurality of signal transmission means for transmitting to the above bus of the output of the above plurality of signal processing means, in response to operation of the above output selection means; and
means for transmitting the signals of the above bus to the above output means (2a).

Further, as indicated in claim 8, it is desirable that the above signal processing and control means have a stereo bus (23);
a submix bus (24);
a plurality of memory means (25a through 251);
a plurality of signal processing means, which perform predetermined signal processing on the respective outputs of the above plurality of memory means (25a through 251) in response to operation of the above signal transmission path selection means;
input signal transmission means for transmitting the signals of the above input means (1a) to the above memory means of, in response to operation of the above input selection means (40a);
a plurality of stereo signal transmission means for transmitting the outputs of the above plurality of signal processing means to the above output means via the above stereo bus (23), in response to operation of the above output selection means;
submix selection means (62), capable of manual operation, for selectively ordering signal transmission via the above submix bus (24);
a submix selection display device (63) disposed in a predetermined positional relationship with the above submix selection means; and
submix signal transmission means for selectively transmitting the output of the above signal processing means to the above memory means via the above submix bus (24), in response to operation of the above submix selection means (62).

Further, as indicated in claim 9, it is desirable that the above signal processing and control means further include means for selectively transmitting signals of the above input means (1a) to the above stereo bus, in response to operation of the above input selection means (40a).

Further, as indicated in claim 10, it is desirable that the above signal processing means include means for adjusting the signal level of the output of the above memory means.

Further, as indicated in claim 11, it is desirable that the above signal processing means be mixer means.

Further, as indicated in claim 12, it is desirable that the signal processing apparatus further includes an operation panel, and that the operation unit of the above input selection switch, the operation unit of the above output selection switch, the operation units of the above plurality of signal transmission path selection switches, the above input display device, the above output display device, and the above plurality of signal transmission path selection display devices, be disposed on the above operation panel.

According to each aspect of the claims of this invention, a plurality of display devices indicating signal transmission paths are sequentially put into display states with a time difference, so that the operator can easily recognize visually the signal transmission paths.

### BRIEF DESCRIPTION OF THE DRAWINGS

FIG. 1 is a block diagram showing a signal processing apparatus according to an embodiment 1 of the present invention;

FIG. 2 is a block diagram showing the functions of the signal processing and control means accompanying the input means, output means, operation means, and display means of FIG. 1;

FIG. 3 is a block diagram showing in detail the functions of a portion of FIG. 2;

FIG. 4 is a plan view showing operation means and display means in a portion of the operation panel of the signal processing apparatus of FIG. 1;

FIG. 5 is an electrical circuit diagram of a portion of the operation panel and display devices of FIG. 4;

FIG. 6 shows a first table stored in the RAM of FIG. 1;

FIG. 7 shows a second table stored in the RAM of FIG. 1;

FIG. 8 shows a third table stored in the RAM of FIG. 1;

FIG. 9 shows a fourth table stored in the RAM of FIG. 1;

FIG. 10 is a flow chart of search processing for a connection destination object;

FIG. 11 is a flow chart of search processing for a connection source object;

FIG. 12 is a plan view showing a portion of FIG. 4, for explaining the display of the first step of a first signal transmission path;

FIG. 13 is a plan view showing a portion of FIG. 4, for explaining the display of the second step of a first signal transmission path;

FIG. 14 is a plan view showing a portion of FIG. 4, for explaining the display of the third step of a first signal transmission path;

FIG. 15 is a plan view showing a portion of FIG. 4, for explaining the display of the fourth step of a first signal transmission path;

FIG. 16 is a plan view showing a portion of FIG. 4, for explaining the display of the fifth step of a first signal transmission path;

FIG. 17 is a plan view showing a portion of FIG. 4, for explaining the display of the sixth step of a first signal transmission path; and

FIG. 18 is a plan view showing a portion of FIG. 4, for explaining the display of the seventh step of a first signal transmission path.

### DESCRIPTION OF THE PREFERRED EMBODIMENTS

Next, aspects of the invention are explained, referring to the drawings.

### Embodiment 1

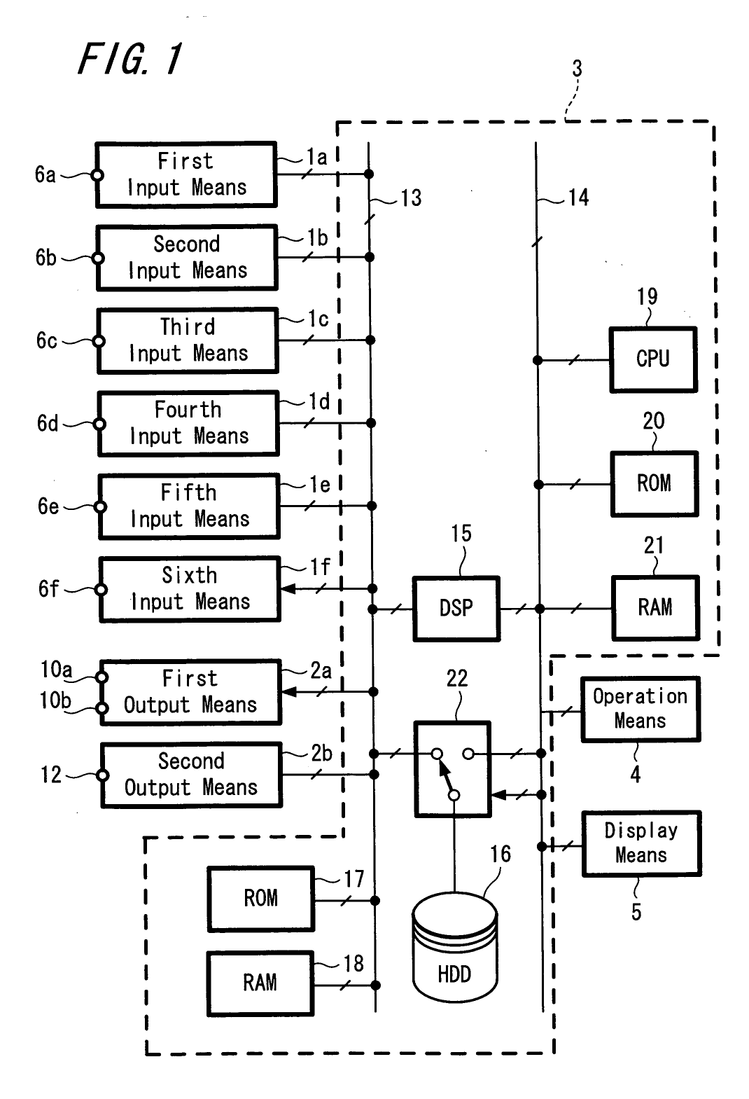

A signal processing apparatus according to an embodiment 1 of this invention, having mixer functions and effector functions, broadly includes first through sixth input means 1a through 1f, first and second output means 2a and 2b, signal processing and control means 3, operation means 4 disposed on a panel, and display means 5, as shown in FIG. 1.

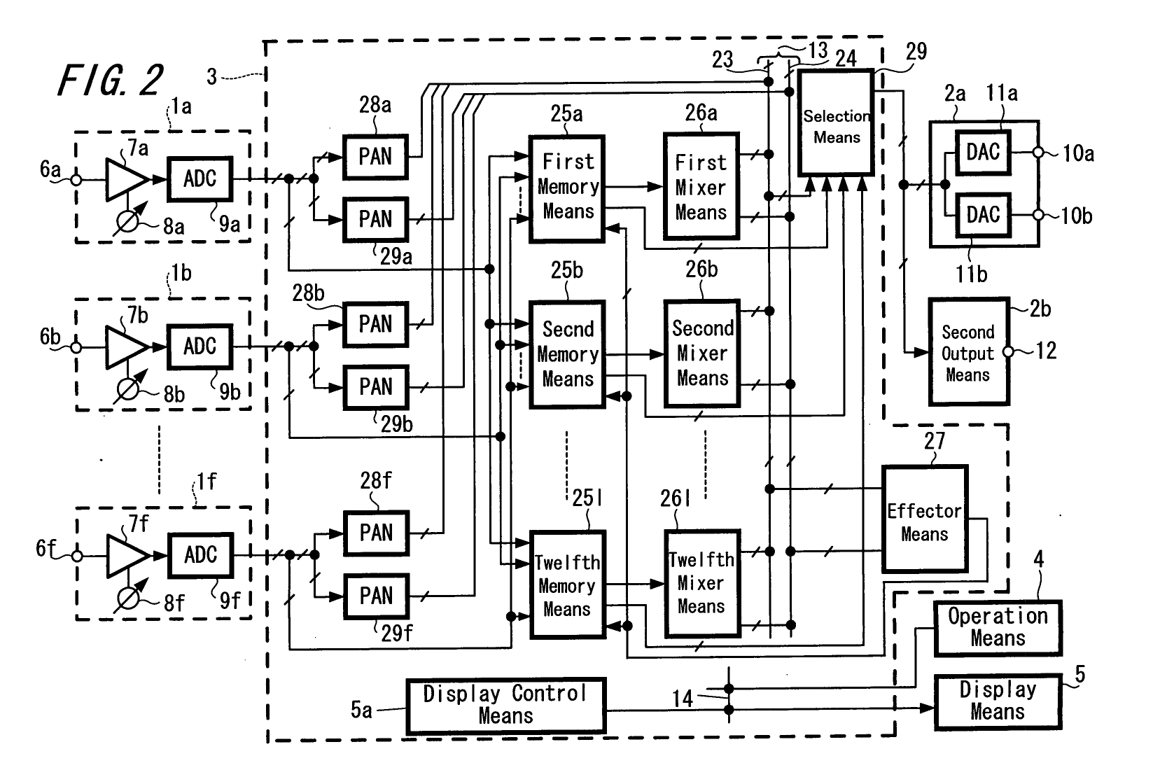

The first through sixth input means 1a through 1f have input terminals 6a through 6f for input of audio signals or other analog signals, and also have amplifiers 7a through 7f, gain control means for trimming 8a through 8f, and analog/digital converters, that is, ADCs, 9a through 9f, as shown in FIG. 2; the analog signals at the input terminals 6a through 6f are converted into digital signals and supplied to the signal processing and control means 3.

The first output means 2a has a pair of output terminals 10a, 10b for converting digital signals supplied from the signal processing and control means 3 into analog signals and for output thereof. Further in detail, as shown in FIG. 2, the first output means 2a has a pair of digital/analog converters, that is, DACs 11a and 11b, connected to the signal processing and control means 3. The second output means 2b connected to the signal processing and control means 3 has a terminal 12 which outputs the output of the signal processing and control means 3 as a digital signal, without converting into an analog signal. In FIGS. 1 and 2, first and second output means 2a and 2b are shown; however, either of these can be omitted, or a greater number of output means can be provided.

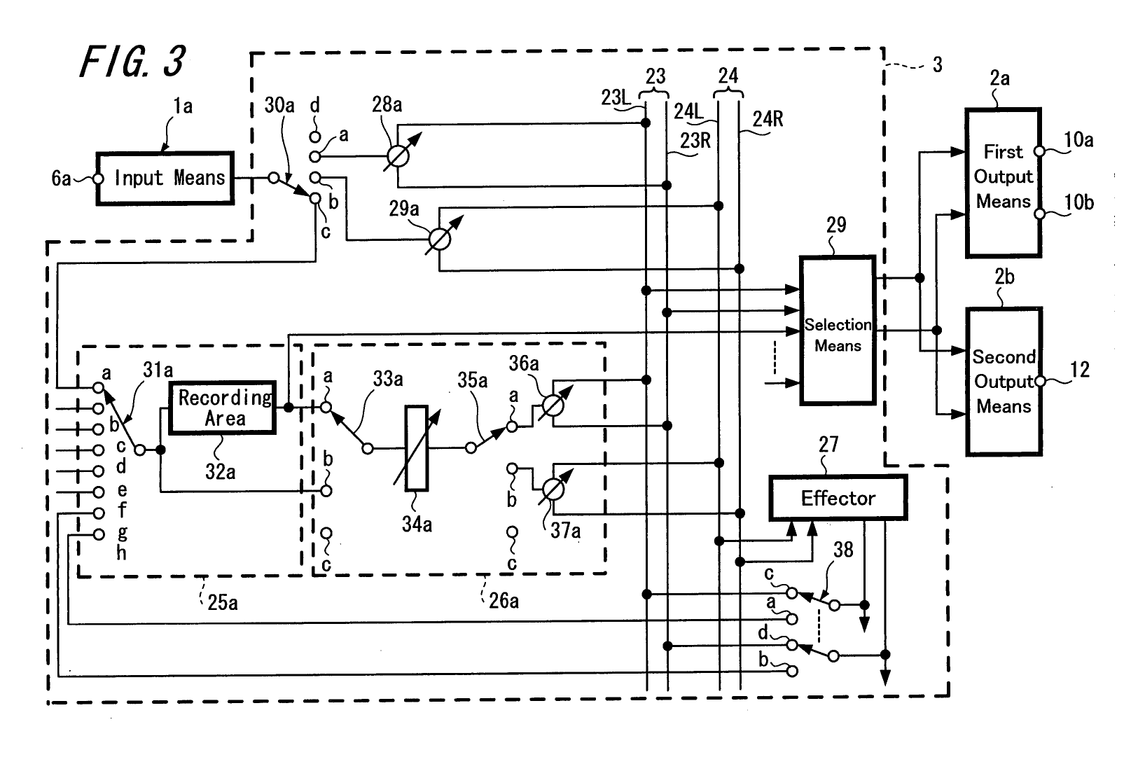

FIG. 1 schematically shows the hardware configuration of the signal processing and control means 3. The signal processing and control means 3 includes a digital audio bus 13, host bus 14, DSP (digital signal processor) 15, hard disk drive (HDD) 16, first ROM 17, first RAM 18, CPU (central processing unit) 19, second ROM 20, second RAM 21, and switching means 22. The digital audio bus 13 is connected to the first through sixth input means 1a through 1f, the first and second output means 2a and 2b, the DSP 15, HDD 16, first ROM 17, and first RAM 18. In FIG. 1, the digital audio bus 13 is schematically shown as a single bus; however, in practical use, as shown in FIGS. 2 and 3, includes a stereo bus 23 which can be called a first bus and a submix bus 24 which can be called a second bus. The submix bus 24 is provided in order to form a signal transmission path which cannot be realized by the stereo bus 23 alone. Audio digital signals supplied from the first through sixth input terminals 1a through 1f are subjected to, for example, mixing processing or effect processing by the audio signal processing means including the DSP 15, HDD 16, ROM 17 and RAM 18, and are then sent to the first and second output means 2a and 2b.

The CPU 19, ROM 20, and RAM 21 connected to the host bus 14 form a microcomputer, which is means for controlling the digital audio signal processing means including the DSP 15, HDD 16 and similar, digital audio signals are subjected to the desired processing according to commands from the operation means 4, and the signal transmission path display control according to the present invention is executed. For this reason, the operation means 4 and display means 5 are connected to the host bus 14. In FIG. 1, the operation means 4 is schematically shown as a single block; however as will be made obvious from description later on, in practical use, various selection means, adjustment means and others are included. Further, in FIG. 1 the display means 5 is schematically shown as a single block; however as will be made obvious from description later on, numerous display devices composed of LEDs (light-emitting diodes) are included. In this embodiment, switching means 22 is provided, because the HDD 16 is used by both the DSP 15 and CPU 19 as memory means.

FIG. 2 is a block diagram showing, functionally or equivalently, the signal processing and control means 3 of FIG. 1 accompanying the input means 1a through 1f and output means 2a and 2b. The signal processing and control means 3 includes: digital audio signal processing means having a stereo bus 23, submix bus 24, first through twelfth signal transmission path formation means or first through twelfth memory means 25a through 251 which can be called first through twelfth tracks, first through twelfth mixer means 26a through 261 as first through twelfth signal processing means, effector means 27, twelve signal distribution means 28a through 28f and 29a through 29f conventionally called pan controls, and output selection means 29, and has the display control means 5a of the present invention. Due to constraints on illustration, in FIG. 2 only three memory means 25a, 25b and 251, and three mixer means 26a, 26b and 261 are shown; however in practical use, also nine remaining memory means which can be indicated by 25c, 25d, 25e, 25f, 25g, 25h, 25i, 25j and 25k, as well as nine remaining mixer means which can be indicated by 26c, 26d, 26e, 26f, 26g, 26h, 26i, 26j and 26k are included. Further, in FIG. 2 only six distribution means 28a, 28b, 28f, 29a, 29b and 29f are shown; in practical use, there are also six remaining signal distribution means which can be indicated by 28c, 28d, 28e, 29c, 29d, 29e.

In FIG. 2, the stereo bus 23 and submix bus 24 are schematically shown as the digital audio bus 13 of FIG. 1, however in practical use there are pairs of transmission paths 23L, 23R and 24L, 24R for transmitting stereo signals, as shown in FIG. 3.

In FIG. 2, the signal distribution means 28a, 28b, and 28f are respectively connected between the first, second and sixth input means 1a, 1b and 1f, and the stereo bus 23. The signal distribution means 29a, 29b, 29f are respectively connected between the first, second, and sixth input means 1a, 1b and 1f, and the submix bus 24. The signal distribution means 28a through 28f and 29a through 29f are selectively connected between the input means 1a through 1f and the two buses 23 and 24 by selection means; the output signals of the first through sixth input means 1a through 1f are distributed in an arbitrary ratio to the first and second lines 23L and 23R of the stereo bus 23 shown in FIG. 3, and are also distributed in an arbitrary ratio to the first and second lines 24L, 24R of the submix bus 24.

The first through twelfth memory means 25a through 251 functioning as the first through twelfth tracks of a 12-channel multi-track recorder, and the first through twelfth mixer means 26a through 261 functioning as 12-channel submixer means, are connected in series and this series circuit is connected between the first through sixth input means 1a through 1f, and the stereo bus 23 and submix bus 24. The first through twelfth memory means 25a through 251 and the first through twelfth mixer means 26a through 261 can be integrated and can be called the first through twelfth channel signal transmission paths.

The effector means 27 is connected between the stereo bus 24 and submix bus 25, and the first through twelfth memory means 25a through 251. The output selection means 29 is connected to the stereo bus 23 and to the first through twelfth memory means 25a through 251, and has functions to select the outputs of these and to send the outputs to the first and second output means 2a and 2b.

The display control means 5a is connected to the operation means 4 and display means 5 via the host bus 14, and controls display of the display means 5.

FIG. 3 is a circuit diagram showing equivalently or functionally in detail, the two signal distribution means 28a and 29a, the first memory means 25a, the first mixer means 26a, and the effector means 27, accompanying the first input means 1a, and first and second output means 2a and 2b. Though not shown in FIG. 3, the remaining signal distribution means 28b through 28f and 29b through 29f, second through twelfth memory means 25b through 251, and second through twelfth mixer means 26b through 261 are also configured similarly to the signal distribution means 28a, 29a, first memory means 25a, and first mixer means 26a in FIG. 3. Hence explanations of the second through twelfth memory means 25b through 251 and of the second through twelfth mixer means 26b through 261 are omitted.

In FIG. 3, selection means 30a is provided for selecting the signal distribution means 28a or 29a. This selection means 30a has first, second, third, and fourth contact points a, b, c and d. When contact point a is selected, the output of the input means 1a is sent to the stereo bus 23 via the distribution means 28a. When contact point b is selected, the output of the input means 1a is sent to the submix bus 24 via the distribution means 29a. When contact point c is selected, the output of the input means 1a is sent to the memory means 25a. When contact point d is selected, transmission of the output of the input means 1a is cut off.

The first memory means 25a includes an input selection switch 31a as shown equivalently in FIG. 3, and a recording area 32a, which can also be called a track. In this embodiment, an HDD 16 is used as the recording area 32a.

The input selection switch 31a has first, second, third, fourth, fifth, and sixth input selection contact points a, b, c, d, e and f, and first and second effector signal selection contact points g and h; and the input signals of the contact points a through h are selected as alternatives, that is, exclusively. The first input selection contact point a is connected to the first input means 1a via the selection switch 30a. Hence the first through sixth contact points a through f function as the first through sixth input selection means according to this invention. The second through sixth input selection contact points b through f are connected to the remaining second through sixth input means 1b through 1f, via similar means to the selection means 30a. The first and second effector signal selection contact points g and h are connected to the submix bus 24 via the selection switch 38 and effector means 27. The first recording area 32a of the memory means 25a is connected to the input selection switch 31a. Hence one of the signals of the contact points a through h, selected by the input selection switch 31a, is written to the recording area 32a. The output of the track, that is, the recording area 32a, is sent to the next-stage mixer means 26a, and is also sent to the output selection means 29.

The mixer means 26a, functioning as signal processing means, includes a mixer input selection switch 33a, signal level adjustment means 34a conventionally called a fader, a signal supply destination selection switch 35a, and two signal distribution means 36a and 37a, conventionally called PANs. The input selection switch 33a has a contact point a connected to the recording area 32a, a contact point b connected to the input selection switch 31a without intervention of the recording area 32a, and a contact point c for setting the off state. The signal level adjustment means 34a adjusts the level of the signal selected by the mixer selection switch 33a. The switch 35a connected to the signal level adjustment means 34a has a contact point a connected to the signal distribution means 36a, a contact point b connected to the signal distribution means 37a, and an off setting contact point c; and the output of the signal level adjustment means 34a is selectively supplied to one among the two signal distribution means 36a and 37a. One signal distribution means 36a distributes the output signal of the signal level adjustment means 34a to the pair of lines 23L and 23R of the stereo bus 23, at a desired ratio. The other signal distribution means 37a distributes the output signal of the signal level adjustment means 34a to the pair of lines 24L and 24R of the submix bus 24, at a desired ratio.

The pair of input terminals of the effector means 27 is connected to the pair of lines 24L and 24R of the submix bus 24, and the pair of output terminals thereof is connected to the contact points g and h of the first memory means 25a via the contact points a and b of the selection switch 38, as well as to the pair of lines 23L and 23R of the stereo bus 23 via the contact points c and d. The effector means 27 is used in common by the first through twelfth memory means 25a through 251, and is also connected to the memory means 25b through 251 in addition to the first memory means 25a shown in FIG. 3.

The signal processing and control means 3 has, in addition to the functions shown in FIGS. 2 and 3, functions of recording control, reproduction control, forward-direction fast-feeding control, reverse-direction feeding control, recording and reproduction halt control, and similar; however, these functions are not directly related to this invention, and so are omitted from the drawings.

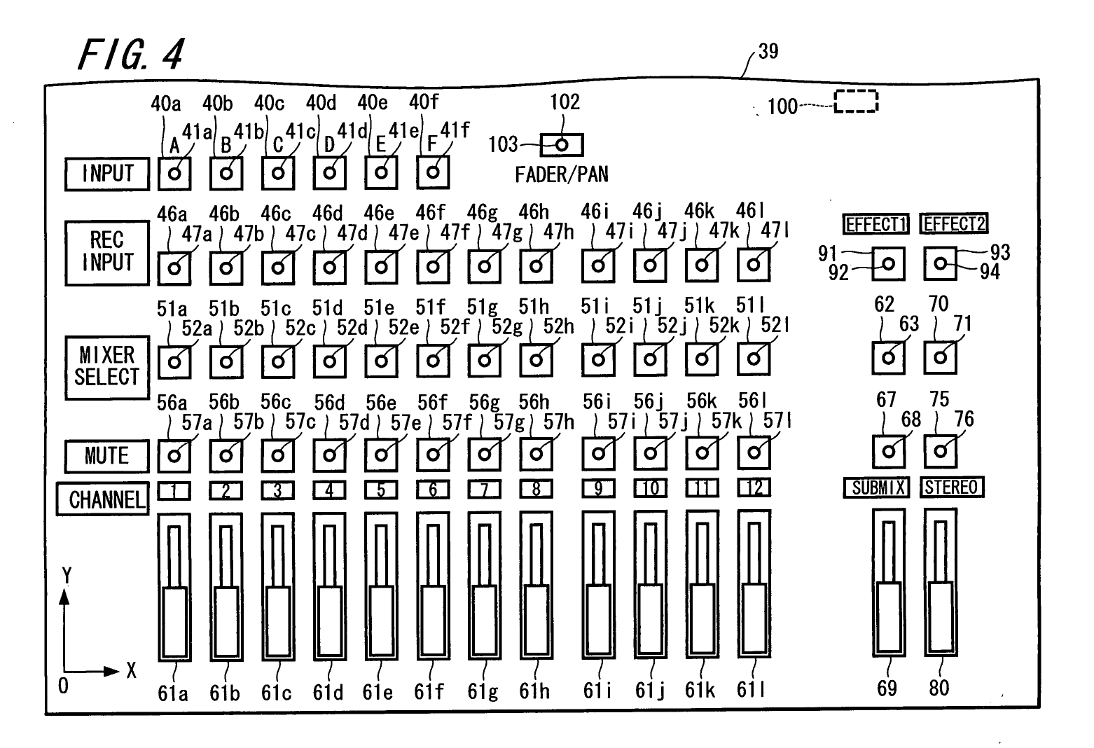

FIG. 4 shows the configuration on the operation panel of the signal processing apparatus of this embodiment. On the operation panel 39 are positioned component members of the operation means 4 and display means 5 of FIG. 1. In further detail, on the operation panel 39 are provided first through sixth input selection buttons 40a, 40b, 40c, 40d, 40e and 40f as the manual operation units of the first, second, third, fourth, fifth, and sixth input selection means. Further, first, second, third, fourth, fifth, and sixth input display devices 41a, 41b, 41c, 41d, 41e and 41f, including LEDs, are provided integrally with respect to the first through sixth input selection buttons 40a, 40b, 40c, 40d, 40e and 40f. Hence the input selection buttons 40a, 40b, 40c, 40d and 40e, 40f also function as a part of the display units of the first, second, third, fourth, fifth, and sixth input display devices 41a, 41b, 41c, 41d, 41e and 41f. In place of being integrally formed with the first through sixth input selection buttons 40a through 40f, the first through sixth input display device 41a through 41f can be disposed on the operation panel 39 in proximity to the respective first through sixth input selection buttons 40a through 40f. The first through sixth input selection buttons 40a through 40f and the first through sixth input display devices 41a through 41f are arrayed, within XY coordinates of the operation panel 39, at a first height position on the Y axis and extending in the X-axis direction, and with “INPUT” printed near this arrangement to indicate correspondence with the first through sixth input means 1a through 1f. Further, “A”, “B”, “C”, “D”, “E” and “F” are printed along the first through sixth input selection buttons 40a, 40b, 40c, 40d, 40e and 40f, to aid recognition of the first through sixth input means 1a through 1f. Of course, in place of “A”, “B”, “C”, “D”, “E” and “F”, “INPUT-A”, “INPUT-B”, “INPUT-C”, “INPUT-D”, “INPUT-E” and “INPUT-F”, or similar, can also be printed along the input selection buttons 40a, 40b, 40c, 40d, 40e and 40f.

The input selection buttons 40a through 40f are portions to manually turn on the push-button type input selection switches 42a through 42f. One terminal of each switch 42a through 42f is connected to the DC power supply terminal 44 via a resistance 43a through 43f, and the other terminal is connected to ground. The interconnection points between the resistances 43a through 43f and the switches 42a through 42f are connected to the CPU 19 of FIG. 1 via the bus 14. In place of the push-button type switches 42a through 42f, touch-switches, which cause the switch to be turned on upon contact by the finger or similar of the operator, can be used.

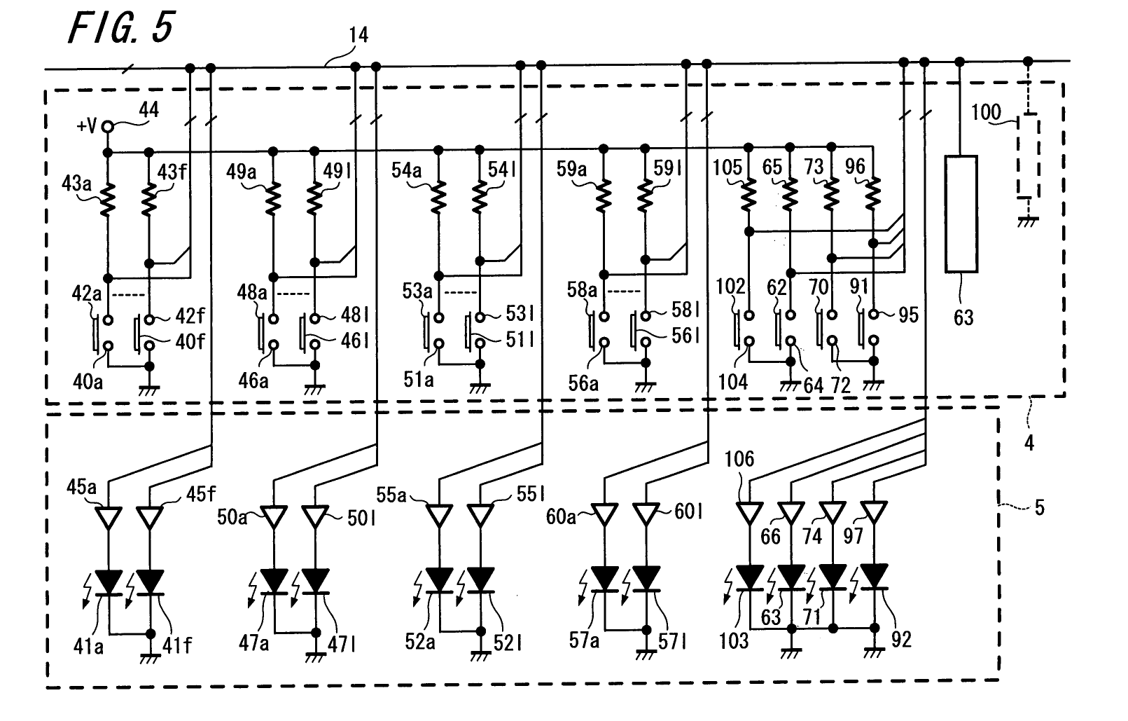

The input display devices 41a through 41f to visually indicate operation of the input selection buttons 40a through 40f are connected to the CPU 19 of FIG. 1 via the driving circuits 45a through 45f and bus 14, as shown in FIG. 5, emitting light in accordance with orders from the CPU 19, and are used both to indicate operation of the input selection buttons 40a through 40f and to indicate signal transmission paths according to this invention.

The first through sixth input selection buttons 40a through 40f of FIG. 4 have functions corresponding to the contact points a through f of the input selection switch 31a in the equivalent circuit of the signal processing and control means 3 of FIG. 3. That is, when the first through sixth input selection buttons 40a through 40f in FIG. 4 are pressed manually, a signal transmission operation occurs which is equivalent to putting in the turned-on state the contact points a through f of the input selection switch 31a of FIG. 3.

First through twelfth recording input selection buttons 46a through 461 are provided on the operation panel 39, as signal transmission path selection means or as signal processing input selection means or as signal processing selection means, to apply signal supply commands to the first through twelfth memory means 25a through 251. Those first through twelfth recording input selection buttons 46a through 461 are arranged in parallel with the arrangement of six input selection buttons 40a through 40f. First through twelfth recording input display devices 47a through 471 are provided integrally with the first through twelfth recording input selection buttons 46a through 461 respectively, having the functions of the signal transmission path selection display devices of this invention. Hence the first through twelfth recording input selection buttons 46a through 461 also function as a part of the display devices of the first through twelfth recording input display devices 47a through 471.

In place of forming the first through twelfth recording input display devices 47a through 471 integrally with the first through twelfth recording input selection buttons 46a through 461 respectively, the recording input display devices can be disposed on the operation panel 39 in proximity to the respective recording input selection buttons 46a through 461. The first through twelfth recording input display devices 47a through 471 are used to display the operation of the recording input selection buttons 46a through 461, and also to display signal transmission paths, according to this invention. In order to aid recognition of the functions of the first through twelfth recording input selection buttons 46a through 461, “REC INPUT” is printed on the operation panel 39 on the left of those buttons. In place of “REC INPUT”, “REC READY”, “TRACK INPUT”, or some other identification text or symbols can be printed. “REC INPUT”, “REC READY”, or some other identifying text or symbols can be printed in proximity to each of the first through twelfth recording input selection buttons 46a through 461.

The recording input selection buttons 46a through 461 are portions for a manual operation to turn on the push-button type recording input selection switches 48a through 481, as shown in FIG. 5. One terminal of each of the switches 48a through 481 is connected to a DC power supply terminal 44 via resistances 49a through 491, and the other terminal is connected to ground. The interconnection points of the resistances 49a through 491 and the switches 48a through 481 are connected to the CPU 19 of FIG. 1 via the bus 14. In place of the push-button type switches 48a through 48f, touch-switches, which cause the switch to be turned on upon contact by the finger or similar of the operator, can be used.

As signal processing input display devices to visually indicate operation of the recording input selection buttons 46a through 461, the recording input display devices 47a through 471 are connected to the CPU 19 via the respective driving circuits 50a through 501 and bus 14, as shown in FIG. 5, emitting light according to commands from the CPU 19, and are used both to display operation of the recording input selection buttons 46a through 461 and to display signal paths according to this invention.

The first through twelfth recording input selection buttons 46a through 461 of FIG. 4 have functions equivalent to the input selection switch 31a in the equivalent circuit of the signal processing and control means 3 of FIG. 3. That is, when the first through twelfth recording input selection buttons 46a through 461 in FIG. 4 are manually pressed, signal transmission to the recording area 32a via the input selection switch 31a of FIG. 3 becomes possible.

As signal processing selection means or mixer selection means or channel selection means on the operation panel 39 to order selection from the first through twelfth mixer means 26a through 261, first through twelfth mixer selection buttons 51a through 511 are provided. The first through twelfth mixer selection buttons 51a through 511 are arrayed in parallel with the arrangement of the twelve recording input selection buttons 46a through 461. As signal processing selection display devices, first through twelfth mixer selection display devices 52a through 521 are provided integrally with the respective first through twelfth mixer selection buttons 51a through 511. Hence the first through twelfth mixer selection buttons 51a through 511 also function as the display units of the first through twelfth mixer selection display devices 52a through 521. In place of forming the first through twelfth mixer selection display devices 52a through 521 integrally with the first through twelfth mixer selection buttons 51a through 511, the mixer selection display devices can be disposed in proximity to the respective first through twelfth mixer selection buttons 51a through 511. The first through twelfth mixer selection display devices 52a through 521 are used to display operation of the mixer selection buttons 51a through 511, and are also used to display signal paths according to this invention. In order to aid recognition of the functions of the first through twelfth mixer selection buttons 51a through 511, “MIXER SELECT” is printed on the operation panel 39, on the left-hand side of the button arrangement. In place of “MIXER SELECT”, “SELECT”, or “CHANNEL SELECT”, or “MIXER OUTPUT”, or other identifying text or symbols can be printed. Further, “MIXER SELECT”, “SELECT”, or some other identifying text or symbols can also be printed in proximity to each of the first through twelfth mixer selection buttons 51a through 511.

The mixer selection buttons 51a through 511 are portions for manual operation to turn on the push-button type selection switches 53a through 531 shown in FIG. 5. One terminal of each of the switches 53a through 531 is connected to the DC power supply terminal 44 via resistance 54a through 541, and the other terminal is connected to ground. The interconnection points between the resistances 54a through 541 and the switches 53a through 531 are connected to the CPU 19 of FIG. 1 via the bus 14. In place of the push-button type switches 53a through 531, touch-switches, which cause the switch to be turned on upon contact by the finger or similar of the operator, can be used.

The mixer display devices 52a through 521 to provide a visual indication of operation of the mixer selection buttons 53a through 531, as signal processing selection display devices or channel display devices, are connected to the CPU 19 via the driving circuits 55a through 551 and bus 14, as shown in FIG. 5, emitting light in accordance with orders from the CPU 19, and are used both to indicate operation of the mixer selection buttons 51a through 511 and to indicate signal transmission paths according to this invention.

The first through twelfth mixer selection buttons 51a through 511 have functions equivalent to the selection switches 33a and 35a in the equivalent circuit of the signal processing and control means 3 of FIG. 3. That is, when the first through twelfth mixer selection buttons 51a through 511 in FIG. 4 are pressed manually, the selection switches 33a, 35a of FIG. 3 make contact with the contact point a or contact point b, and a mixer signal transmission path is formed.

As first through twelfth interruption selection means, first through twelfth mute selection buttons 56a through 561 are disposed on the operation panel 39, in parallel with the row of first through twelfth recording input selection buttons 46a through 461 and the row of first through twelfth mixer selection buttons 51a through 511. The mute selection buttons are for manual turn-on operation when selectively cutting off signal transmission through the first through twelfth memory means 25a through 251 and first through twelfth mixer means 26a through 261. First through twelfth mute display devices 57a through 571 are provided integrally with the respective first through twelfth mute selection buttons 56a through 561. In place of integrally forming with the first through twelfth mute selection buttons 56a through 561, the first through twelfth mute display devices 57a through 571 can be disposed on the operation panel 39 in proximity to the respective first through twelfth mute selection buttons 56a through 561. The first through twelfth mute display devices 57a through 571 are used to display operation of the mute selection buttons 56a through 561. In order to aid recognition of the functions of the first through twelfth mute selection buttons 56a through 561, “MUTE” is printed on the operation panel 39 on the left of those buttons. Further, “MUTE” or other identifying text or symbols can be printed in proximity to each of the first through twelfth mute selection buttons 56a through 561.

The mute selection buttons 56a through 561 are portions for manual turn-on operation of the push-button type mute selection switches 58a through 581, as shown in FIG. 5. One terminal of each of the switches 58a through 581 is connected to the DC power supply terminal 50 via resistances 59a through 591, and the other terminal is connected to ground. The interconnection points of the resistances 59a through 591 and the switches 58a through 581 are connected to the CPU 19 of FIG. 1 via the bus 14.

The mute display devices 57a through 571 to provide a visual indication of operation of the mute selection buttons 56a through 561 are connected to the CPU 19 in FIG. 1 via the driving circuits 60a through 601 and bus 14, as shown in FIG. 5, emitting light in accordance with orders from the CPU 19, and are used to indicate operation of the mute selection buttons 56a through 561.

The first through twelfth mute selection buttons 56a through 561 have functions equivalent to contact point c of the selection switches 33a and 35a in the equivalent circuit of the signal processing and control means 3 of FIG. 3. That is, when the first through twelfth mute selection buttons 56a through 561 of FIG. 4 are manually pressed, the contact point c of the selection switches 33a and 35a in FIG. 3 is turned on, and signal transmission is cut off.

First through twelfth level adjustment devices 61a through 611 for adjusting the signal levels in signal transmission paths are provided. Those first through twelfth level adjustment devices 61a through 611 generate adjustment signals as a result of manual operation, and send the signals to the CPU 19 via the bus 14. In this embodiment, the first level adjustment device 61a functions as the signal level adjustment means 34a and signal distribution means 28a, 29a, 36a and 37a in FIG. 3. When using the first through twelfth level adjustment devices 61a through 611 as the signal level adjustment means 34a, the lockable FADER/PAN switch button 102 of FIG. 4 is operated by pressing, and when used as the signal distribution means 28a, 29a, 36a and 37a, the FADER/PAN switch button 102 is pressed once again to cancel the locked state. The second through twelfth level adjustment devices 61b through 611 also have the same functions as the level adjustment device 61a. In this embodiment, in order to simplify the configuration of the signal processing apparatus, the first through twelfth level adjustment devices 61a through 611 are shared by the fader and pan controls; but independent adjustment devices for the fader and pan controls can also be provided.

The FADER/PAN switch button 102 is provided as an operation unit of the switch 103 shown in FIG. 5. The switch 103 is connected to the CPU 19 of FIG. 1 via the bus 14, and selectively outputs the signal indicating “FADER” and the signal indicating “PAN”. For example, when the switch button 102 is operated to select PAN and the input selection button 40a is operated, the level adjustment device 61a of FIG. 4 functions as the distribution devices 28a and 29a of FIG. 3. When the switch button 102 is operated to select PAN and the mixer selection button 51a is operated, the level adjustment device 61a functions as the distribution devices 36a and 37a of FIG. 3. Further, when the switch 102 is operated to select FADER and the mixer selection button 51a is operated, the level adjustment device 61a functions as the level adjustment means 34a of FIG. 3.

On the operation panel 39 of FIG. 4, the first through twelfth recording input selection buttons 46a through 461, first through twelfth mixer selection buttons 51a through 511, first through twelfth mute selection buttons 56a through 561, and first through twelfth level adjustment devices 61a through 611 are arranged regularly so as to extend in the Y-axis direction for each channel, and in order to aid identification of the channel, numbers from 1 to 12 are printed between the mute buttons 56a through 561 and the level adjustment devices 61a through 611, and “CHANNEL” is printed on the left of the numbers.

A submix selection button 62 and submix display device 63 integrally formed therewith are provided, for selection of signal transmission to the submix bus 24 shown in FIG. 3. In place of integrally forming the submix display device 63 with the submix selection button 62, the submix display device can be disposed in proximity to the submix selection button 62. The submix selection button 62 is the manual operation unit of the push-button type submix selection switch 64 shown in FIG. 5. One terminal of the submix selection switch 64 is connected to the power supply terminal 44 via a resistance 65, and the other terminal is connected to ground. The interconnection point of the resistance 65 and the submix selection switch 64 is connected to the CPU 19 of FIG. 1 via the bus 14. The submix display device 63 to display operation of the submix selection button 62 is connected to the CPU 19 via the driving circuit 66 and bus 14, and emits light in response to light emission commands from the CPU 19. The submix selection button 62 and display device 63 are positioned to the right of the row of mixer selection buttons 51a through 511 on the panel 39. The submix selection button 62 and switch 64 have the functions of the contact point b of the selection switches 30a and 35a in FIG. 3, and enable signal transmission to the submix bus 24. Note that the output of the submix bus 24 is never transferred simultaneously to a plurality of signal processing objects. Hence the submix selection button 62 can be called the signal processing selection means or signal transmission path selection means, and the submix display device 63 can be called a signal processing display device or signal transmission path display device.

A submix mute button 67 and display device 68 therefor are disposed below the submix selection button 62 in FIG. 4. This button is pressed to interrupt submix operation.

The submix output level adjustment device 69 positioned below the submix mute button 67 is omitted from FIG. 3, but functions as a fader, and adjusts the signal level of the line to extract signals from the submix bus 24. As identifying text or symbols to indicate the submix bus, “SUBMIX” is printed in the portion of the operation panel 39 between the submix mute button 67 and the submix level adjustment device 69.

In order to select signal transmission to the stereo bus 24 shown in FIG. 3 and output from the stereo bus 24, a stereo selection button 70 having the functions of output selection means, and a stereo display device 71 integrated therewith, are provided. In place of integrally forming with the stereo selection button 70, the stereo display device 71 can be disposed in proximity to the stereo selection button 70. The stereo selection button 70 is the manual operation unit of the push-button type stereo selection switch 72 shown in FIG. 5. One terminal of the stereo selection switch 72 is connected to the power supply terminal 44 via the resistance 73, and the other terminal is connected to ground. The interconnection point of the resistance 73 and the stereo selection switch 70 is connected to the CPU 19 of FIG. 1 via the bus 14. The stereo display device 71 to display operation of the stereo selection button 70 is connected to the CPU 19 via the driving circuit 74 and bus 14, and emits light in response to light emission commands from the CPU 19. The stereo selection button 70 and display device 71 are disposed to the right of the submix selection button 62 on the operation panel 39. The stereo selection button 70 and switch 72 have the functions of the contact point a of the selection switches 30a and 35a of FIG. 3, and execute signal transmission to the stereo bus 23. The stereo selection button 70 and switch 72 select transfer of signals of the stereo bus 23 to the first and second output means 2a and 2b in the output selection means 29. Hence the stereo selection button can be called the output selection means, and the stereo display device 71 can be called the output display device.

A stereo mute button 75 and display device 76 therefor are positioned below the stereo selection button 70 in FIG. 4. This button is pressed when interrupting stereo bus operation. The stereo output level adjustment device 77 disposed below the stereo mute button 75 functions as a fader, omitted in FIG. 3, and adjusts the level of the output signal from the stereo bus 23. As identifying text or symbols indicating the stereo bus, “STEREO” is printed in the portion of the operation panel 39 between the stereo mute button 75 and the stereo level adjustment device 77.

A first effector selection button 91 to select operation of the effector means 27 to perform desired processing on signals of the submix bus 24 shown in FIG. 3 and to return the signals to the first through twelfth memory means 25a through 251, and a first effector display device 92 integrated therewith, are provided. Also, although omitted from FIG. 3 and FIG. 5, in FIG. 4 a second effector selection button 93 and display device therefor 94 are also provided. In FIG. 4, the first and second effector selection buttons 91 and 93 are positioned above the submix selection button 62 and stereo selection button 70. The effector selection button 91 is the manual operation unit of the push-button type effector selection switch 95 shown in FIG. 5. One terminal of the effector selection switch 95 is connected to the power supply terminal 44 via the resistance 96, and the other terminal is connected to ground. The interconnection point of the resistance 96 and the effector selection switch 95 is connected to the CPU 19 of FIG. 1 via the bus 14. The effector display device 92 to display operation of the effector selection button 91 is connected to the CPU 19 via the driving circuit 97 and bus 14, and emits light in response to light emission commands from the CPU 19. Electrical circuits for the second effector selection button 93 and display device therefor 94 are not shown in FIG. 5, however are formed similarly to the first effector selection button 91 and display device 92. As identifying text or symbols to indicate the effector, “EFFECT 1” and “EFFECT 2” are printed on the operation panel 39 above the first and second effector selection buttons 91 and 93.

The effector selection buttons 91 and 93 can also be called signal processing selection means or signal transmission path formation means, and the effector display devices 92 and 94 can also be called signal processing display devices or signal transmission path selection display devices.

Various operation units, terminals and display units other than those shown in FIG. 4 are provided on the operation panel of FIG. 4; however since those units are not directly related to this invention, they are omitted from the drawings.

The buttons 40a through 40f, 46a through 461, 51a through 511, 56a through 561, 62, 67, 70, 75, 91, 93, 102 and the level adjustment devices 61a through 611 shown in FIG. 4 are not directly connected to the signal paths of FIGS. 2 and 3, but are to provide commands to the CPU 19 of FIG. 1. The CPU 19 scans the switches and level adjustment devices of FIGS. 4 and 5 and reads operation states, and executes the desired control according to a predetermined connection program stored in ROM 20. In this embodiment, similarly to the above-described patent reference 2, control is executed considering each button, each switch, and each display device to be an “object”. For example, in order to realize the formation of a connection, that is, the formation of a data transmission path between two objects, the buttons corresponding to the two objects are pressed simultaneously, and information indicating this connected relationship is written to RAM 21. When the buttons of two objects are pressed simultaneously and a virtual connection is realized, the display devices for each of the buttons are lit for a fixed length of time, for example 1.5 seconds, and thereafter flash with a period of one second. This display control is executed by the CPU 19.

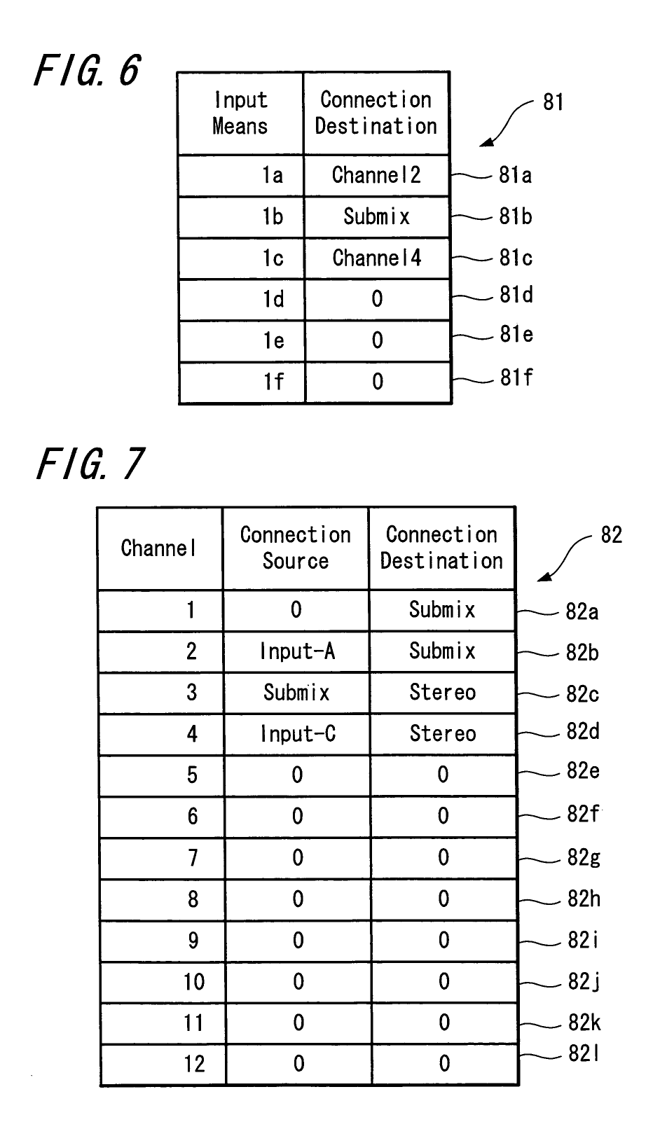

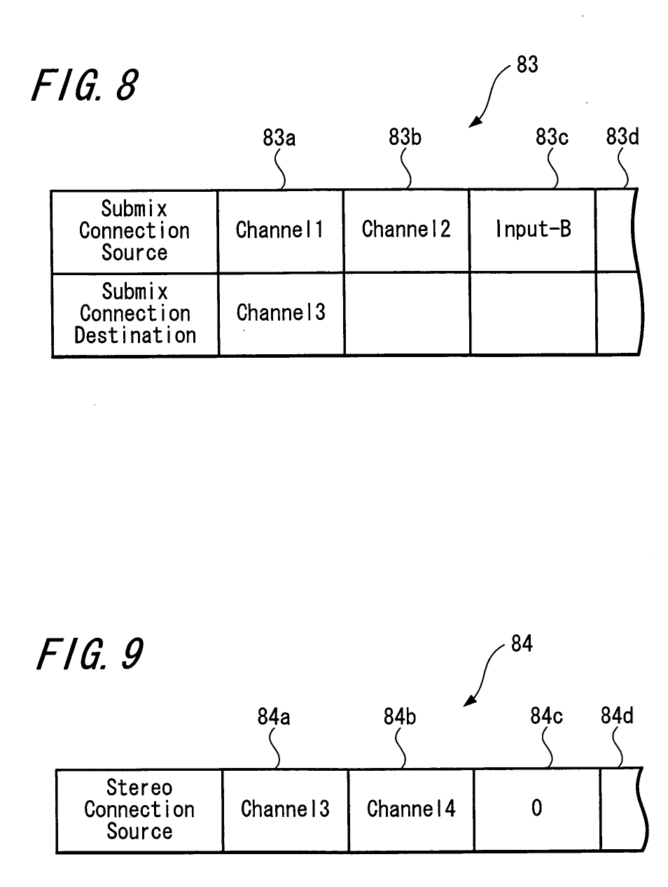

In order to execute formation of a desired signal transmission path according to this embodiment, the RAM 21 of FIG. 1 has first, second, third, and fourth tables 81, 82, 83 and 84, shown in FIGS. 6 through 9. Information indicating signal transmission paths is written to each of the tables 81 through 84. The first table 81 in FIG. 6 has first through sixth areas 81a through 81f, which can be called variables storing object names indicating connection destinations of first through sixth input means 1a through 1f. The first through sixth input means 1a through 1f do not have a connection source, and so the first table 81 does not have a storage area for connection source object names. The second table 82 in FIG. 7 has first through twelfth areas 82a through 821 for storing the object names of connection sources and the object names of connection destinations of first through twelfth channels including first through twelfth memory means 25a through 251 and first through twelfth mixer means 26a through 261 shown in FIG. 2. The third table 83 in FIG. 8 has a plurality of areas 83a through 83d for storing object names of the connection sources and object names of connection destinations of the submix bus 24. The fourth table 84 in FIG. 9 has a plurality of areas 84a through 84d for storing the object names of connection sources of the stereo bus 23. The stereo bus 23 can be regarded as a part of the signal output means, and so does not have an area for storing the object names of connection destinations.

In this embodiment, in order to establish a connection relationship between two objects, two selection buttons corresponding to the two objects are turned on simultaneously. FIGS. 6 through 9 show the contents of the tables 81 through 84 when forming the following four signal transmission paths.

(1) A first signal transmission path, including the first input means 1a, second memory means 25b of the second channel, second mixer means 26b, submix bus 24, third memory means of the third channel, third mixer means, and stereo bus 23

(2) A second signal transmission path, including the second input means 1b, submix bus 24, third memory means of the third channel, third mixer means, and stereo bus 23

(3) A third signal transmission path, including the third input means 1c, fourth memory means of the fourth channel, fourth mixer means, and stereo bus 23

(4) A fourth signal transmission path, including the first memory means 25a of the first channel, first mixer means 26a, submix bus 24 and third memory means of the third channel, third mixer means, and stereo bus 23

For example, in order to form the above first signal transmission path, initially the first input selection button 40a and second recording input selection button 46b in FIG. 4 are turned on simultaneously. As a result, “CHANNEL 2” is written as an object name to the first area 81a of the first table 81 in FIG. 6., and “INPUT-A”, indicating the first input means 1a, is written to the connection source of the second area 82b in the second table 82 of FIG. 7. Accordingly, a connection relationship is established between the first input means 1a and the second memory means 25b of the second channel. Next, the second mixer selection button 51b of the second channel and the submix selection button 62 are turned on simultaneously. As a result, “SUBMIX” is written to the connection destination of the second area 82b of the second table 82 in FIG. 7, and further “CHANNEL 2” is written to the second area 83b of the third table in FIG. 8. Accordingly, a signal transmission path is formed between the second mixer means 26b of the second channel and the submix bus 24. Next, the submix selection button 62 and the third recording input selection button 46c of the third channel are turned on simultaneously, upon which “CHANNEL 3” is written to the submix connection destination field of the first area 83a in the third table 83 of FIG. 8, and moreover “SUBMIX” is written to the connection source field of the third area 82c in the second table 82 of FIG. 7. Accordingly, a connection is established between the submix bus 24 and the third memory means of the third channel. Next, the mixer selection button 52c of the third channel and the stereo selection button 70 are turned on simultaneously, upon which “STEREO” is written to the connection destination field of the third area 82c in the second table 82 of FIG. 7, and moreover “CHANNEL 3” is written to the first area 84a of the fourth table 84 of FIG. 9. Accordingly, a connection is established between the third mixer means of the third channel and the stereo bus 23. Formation of the above second through fourth signal transmission paths can be executed by the same method as for formation of the first signal transmission path.

As is clear from the above explanation of connection operations, when the output of the input means 1a through 1f or submix bus 24, or of another connection source object, is to be input to a channel, the button indicating the connection source object is pressed simultaneously with one of the recording input selection buttons 46a through 461 of a channel, and when the output of a channel which is to be a connection source is to be connected to the submix bus or another object as the connection destination, one of the first through twelfth mixer selection buttons 51a through 511 of each channel is selected and pressed simultaneously with the button of the connection destination object. Hence the first through twelfth recording input selection buttons 46a through 461 function as input selection buttons for each channel, and the first through twelfth mixer selection buttons 51a through 511 function as output selection buttons for each channel.

When buttons corresponding to objects for which a connection relationship is already established are again pressed simultaneously, the connection relationship is canceled. For example, when the first input selection button 40a and second recording input selection button 46b, between which a connection relationship has already been established, are again pressed simultaneously, the name “CHANNEL 2” which had been written to the area 81a of the first table 81 in FIG. 6 is erased, and the name “INPUT-A” which had been written to the connection destination of the area 82b in the second table 82 of FIG. 7 is also erased.

When the button of one object of a pair of objects for which a connection relationship is already established and the button of an object not paired with the former object are pressed simultaneously, the connection relationship which had been established until then is overwritten by the new connection relationship. For example, in a state in which the first input means 1a and second memory means 25b of the second channel are already in a connected relationship, if the first input selection button 40a and the third recording input selection button 46c of the third channel are pressed simultaneously, “CHANNEL 2”, which had been written to the first area 81a of the first table 81 in FIG. 6, is overwritten by “CHANNEL 3”, and moreover “INPUT-A” in the connection source field of the second area 82b of the second table 82 in FIG. 7 is deleted, and instead “INPUT-A” is written to the connection source field of the third area 82c in the second table 82, while “CHANNEL 3” in the connection destination field of the first area 83a in the third table 83 of FIG. 3 is deleted.

The connection information in the above-described first through fourth tables 81 through 84 in RAM 21 is converted into a control program for the DSP 15 and sent to the DSP 15 each time the connection state is changed. The DSP 15 performs digital audio data input/output control by specifying bus addresses.

Display by the display devices 41a through 41f, 47a through 471, 52a through 521, 57a through 571, 63, 68, 71, 76, 92, and 94, which visually indicate operation of the buttons 40a through 40f, 46a through 461, 51a through 511, 56a through 561, 62, 67, 70, 75, 91, and 93 in signal transmission paths, as well as display to visually indicate signal transmission paths according to this invention, are executed by the display control means 5a, functionally represented in FIG. 2.

For example, in a state in which a connection path is established including the above-described first signal transmission path, that is, the first input means 1a, second memory means 25b of the second channel, second mixer means 26b, submix bus 24, third memory means of the third channel, third mixer means, and stereo bus 23, if for example the second recording input selection button 46b or the second mixer selection button 51b contributing to formation of the first signal transmission path is pressed continuously for a longer time (for example, three seconds) than the time for normal turn-on operation (for example, one second), this extended-press information is sent from the bus 14 to the CPU 19, the CPU 19 generates a signal transmission path display command, and the display devices 41a, 47b, 52b, 63, 47c, 52c and 70 relating to the first signal transmission path are lit in sequence, according to a display program in accordance with this invention. In place of an extended press of a signal transmission path button, signal transmission path display command generation means 100 can be provided on the operation panel 39, as shown by the dashed line in FIG. 4, connected to the CPU 19 via the bus 14 as shown in FIG. 5, for use in applying signal transmission path display commands to the CPU 19.

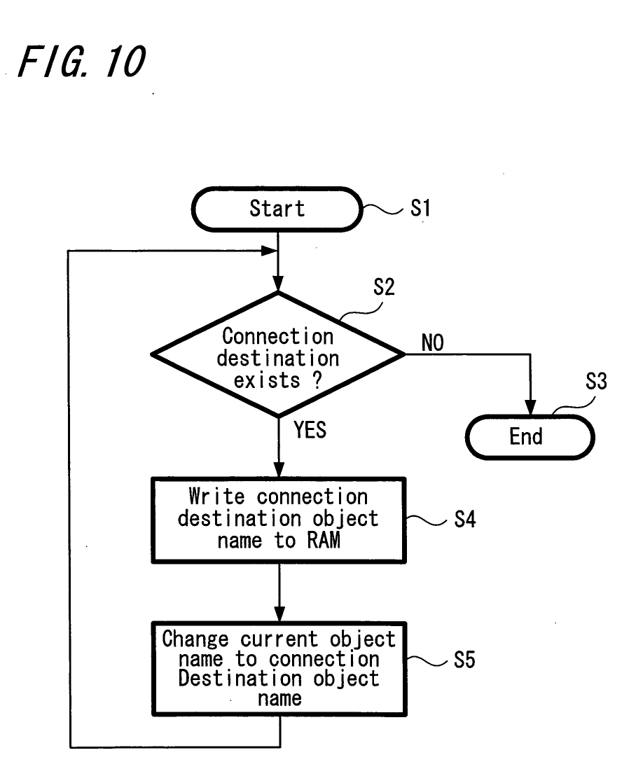

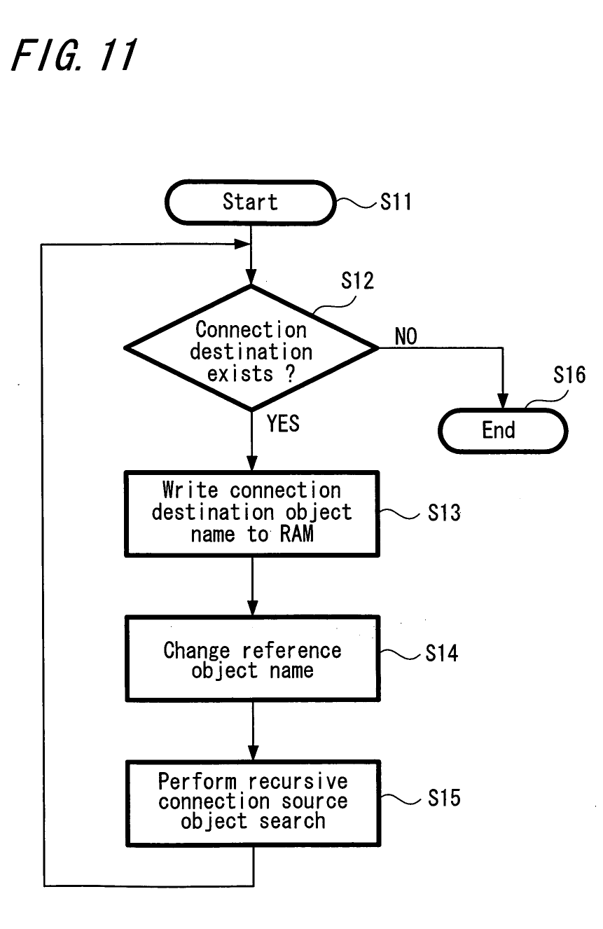

FIGS. 10 and 11 show programs for collecting, from the tables 81 through 84, connection information necessary for display of a signal transmission path as a result of an extended press of a button associated with the signal transmission path. This program is stored in the ROM 20 of FIG. 1. In response to an extended press of a button associated with the signal transmission path, the CPU 19 reads the contents of the first through fourth tables 81 to 84 in RAM 21, detects the signal transmission path in accordance with the program in ROM 20, and sequentially causes light emission of display devices associated with the signal transmission path. Next, processing to acquire connection information on a signal transmission path is explained in detail.

When an arbitrary button associated with a signal transmission path is pressed for an extended length of time, processing to retrieve a connection destination object of, as well as processing to retrieve a connection source object of, the object associated with the button which has been pressed, are executed.

In the connection destination object search processing of FIG. 10, when processing is begun in step S1, a judgment is made as to whether a connection destination object exists or not in step S2. If in step S2 the output “NO” is obtained, indicating that there is no connection destination object, then in step 53 the search processing ends. If in step S2 the output “YES” is obtained, indicating that there is a connection destination object, then in the next step S4 the connection destination object name is written to a signal transmission path display area in RAM 21. Next, in step S5 the object name which is currently shown is rewritten to the connection destination object name written to RAM 21 in step 4. That is, the name of the object of one step ahead, which is the next destination in the signal transmission path relative to the object for which there has been an extended press of a button, or which is the current reference object, becomes the name of the new reference object. Processing then returns to step S2, a judgment is made as to whether a connection destination exists for the new reference object as rewritten in step S5, and when there is a connection destination, the steps S2, S4 and S5 are repeated. Accordingly, as long as there is a connection destination object, object names are appended in sequence to the storage area for the signal transmission path in RAM 21, and when there is no longer a connection destination object, the search ends at step S3.

In this embodiment, after the connection destination object search processing of FIG. 10 has ended, the connection source object search processing of FIG. 11 is executed. Conversely, the connection destination object search processing of FIG. 10 can also be executed after the connection source object search processing of FIG. 11. In step S11 of FIG. 11, connection source object search processing is begun, and in the next step S12 a judgment is made as to whether there exists a connection source object, that is, an object being one step on the “upstream” side of the current reference object, which may be for example the object for which there has been an extended press of a button. If in step S12 the output “YES” is obtained indicating that there is a connection source object, in the next step S13 the connection source object name is written to the signal transmission path storage area in RAM 21. Then, in step S14 the name of the object currently being shown, that is, the reference object name, is overwritten with the connection source object name which was written to RAM 21 in step S13. That is, the name of the object which is the reference for the search for connection source objects is changed to the new object name. Then, in step S15 the processing to search for a connection source object, taking as reference the new object as modified in step S14, is executed recursively. When the connection source object search processing is performed recursively until in step S12 a “NO” output is obtained indicating that there is no longer a connection source object, then in step S16 the program ends.

Next, in a state in which the above-described first, second, third, and fourth signal transmission paths are formed, operation when visually verifying the first, second, third, and fourth signal transmission paths related to the third channel is explained, referring to the flowcharts of FIGS. 10 and 11.

When the third mixer selection button 51c is pressed for an extended period of, for example, three seconds or longer, operation begins according to the flowchart of FIG. 10, and when the above first through fourth signal transmission paths are formed, the third mixer means corresponding to the third mixer selection button 51c is connected to the stereo bus 23, so that the output of step S2 is “YES”, and “STEREO” is written as the connection destination object name to RAM 21 in step S4. In step S5, the reference object is rewritten from “CHANNEL 3” to “STEREO”. Then, processing returns to step S2, a judgment is made as to whether a connection destination object exists for “STEREO”, and because “STEREO” is the final-stage object and has no connection destination object, the output of step S2 is “NO” and so the connection destination object search processing of FIG. 10 ends.

Next, the connection source object search processing of FIG. 11 is begun, as indicated in step S11. In step S12, a judgment is made as to whether there is a connection source object, with reference to the third mixer means of the third channel, corresponding to the third mixer selection button 51c which has been pressed for an extended period of time. In this embodiment, the first through twelfth memory means 25a through 251 and the first through twelfth mixer means 26a through 261 are together defined respectively as the first through twelfth channels, so that even if there is an extended press of one of the first through twelfth recording input selection buttons 46a through 461 or of one of the first through twelfth mixer selection buttons 51a through 511, the respective channel of the first through twelfth channels is regarded to have been specified. Further, in this embodiment it is assumed that neither of the two effector selection buttons 75 and 77 in FIG. 4 has been pressed, and that the submix bus 24 bypasses the effector means 27 and is connected to the third memory means of the third channel. Accordingly, based on the tables 81 through 84, it is determined that the third channel connection source object is the submix bus 24, and so “YES” is output in step S12, and in the next step S13 “SUBMIX” is written to RAM 21. “CHANNEL 3-STEREO” has already been written to the RAM 21, and so upon adding “SUBMIX”, the storage state “SUBMIX-CHANNEL 3-STEREO” occurs. Next, in step S14 the reference object name is changed from “CHANNEL 3” to “SUBMIX”. Then, in step S15 a connection source object search is executed recursively, with “SUBMIX” as reference. As a result, “CHANNEL 1” is detected as a connection source object of “SUBMIX”, and the writing state “CHANNEL 1-SUBMIX-CHANNEL 3-STEREO” occurs in the RAM 21. Next, a connection source object search is performed with “CHANNEL 1”, furthest upstream in the above signal transmission path, as reference. In the above-described first through fourth signal transmission paths, it is determined from the tables 81 through 84 that there is no connection source object for “CHANNEL 1”, so that the connection source object search for “CHANNEL 1” ends, and the reference object name is returned to “SUBMIX”. In processing up to this point, the above-described fourth signal transmission path is stored in RAM 21.

Next, a connection source object search is performed recursively, taking “SUBMIX” to be the reference object; based on the tables 81 through 84, it is determined that “CHANNEL 2” is a connection source object, and so “CHANNEL 2” is added to RAM 21. In this case, the signal transmission path on the downstream side from “SUBMIX” is used copying the above-described fourth signal transmission path, and in the RAM 21 the following write state is obtained:
“CHANNEL 1-SUBMIX-CHANNEL 3-STEREO”
“CHANNEL 2-SUBMIX-CHANNEL 3-STEREO”

Next, the reference object is changed from “SUBMIX” to “CHANNEL 2”, and a search is performed for a connection source object of “CHANNEL 2”. As is clear from the above-described first signal transmission path, the “INPUT-A” object of the first input means 1a is a connection source for “CHANNEL 2”, and so “INPUT-A” is added to the RAM 21, to obtain the write state:
“CHANNEL 1-SUBMIX-CHANNEL 3-STEREO”
“INPUT-A-CHANNEL 2-SUBMIX-CHANNEL 3-STEREO”

Next, a connection source object search is performed with “INPUT-A” as the reference object name. However, it is judged that there is no connection source object for “INPUT-A”, and so the reference object name is returned to “CHANNEL 2”, which is the next object downstream from “INPUT-A”.

Again a connection source object search is performed recursively with “CHANNEL 2” as the reference object. However, there is no connection source object for “CHANNEL 2”, and so a recursive connection source object search is performed with the reference object set to “SUBMIX”, which is the next object downstream from “CHANNEL 2”. Accordingly, it is determined that “INPUT-B”, indicating the second input means 1a, is a connection source object, as is clear from the above-described second signal transmission path, and so this is added to “SUBMIX” and a copy of the signal transmission path on the downstream side from this, to result in the following write state in the RAM 21:
“INPUT-A-CHANNEL 2-SUBMIX-CHANNEL 3-STEREO” (first signal transmission path)
“INPUT-B-SUBMIX-CHANNEL 3-STEREO” (second signal transmission path)
“CHANNEL 1-SUBMIX-CHANNEL 3-STEREO” (fourth signal transmission path)

Next, a connection source object search is performed with “INPUT-B” as the reference object. However, there is no connection source for “INPUT-B”, and so a connection source object search is performed recursively with “SUBMIX”, the next object downstream from “INPUT-B”, as the reference object. There is no connection source object other than that already read, and so the reference object returns to “CHANNEL 3” of one step downstream side from “SUBMIX” and of the reference object at the time the program was started. A judgment is made as to whether there are any connection destination objects which have not yet been read with “CHANNEL 3” as the reference object. In this example, there are no other connection destination objects, and so the program ends.

As is clear from the above explanation, upon performing connection destination object searches and connection source object searches according to the flowcharts of FIGS. 10 and 11, based on the first through fourth tables 81 to 84 in RAM 21, among the above first through fourth signal transmission paths, data describing the first, second and fourth signal transmission paths, which are related to “CHANNEL 3”, is stored in RAM 21 as follows.
“INPUT-A-CHANNEL 2-SUBMIX-CHANNEL 3-STEREO” (first signal transmission path)
“INPUT-B-SUBMIX-CHANNEL 3-STEREO” (second signal transmission path)
“CHANNEL 1-SUBMIX-CHANNEL 3-STEREO” (fourth signal transmission path)

Based on data describing the above first, second and fourth signal transmission paths, the CPU 19 causes the corresponding display devices to emit light sequentially, with time differences.

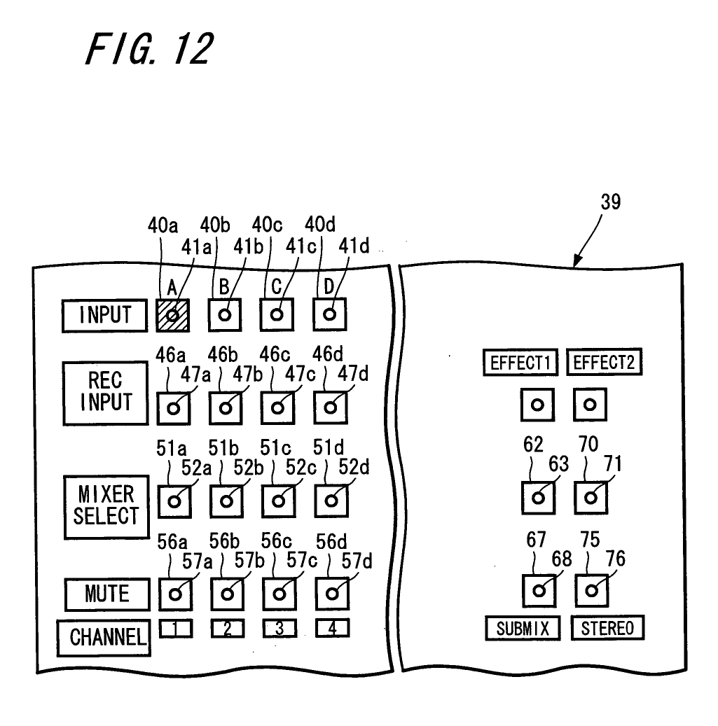

Next, the processing by the display control means 5a shown functionally in FIG. 2 for lighting of the first through sixth input display devices 41a through 41f, first through twelfth recording input display devices 47a through 471, first through twelfth mixer display devices 52a through 521, submix display device 63, and stereo display device 71, as the display means 5, is explained in greater detail, referring to FIG. 12 through FIG. 18. In FIG. 12 through FIG. 18, diagonal shading is applied to lighting devices emitting light and to the buttons corresponding thereto.

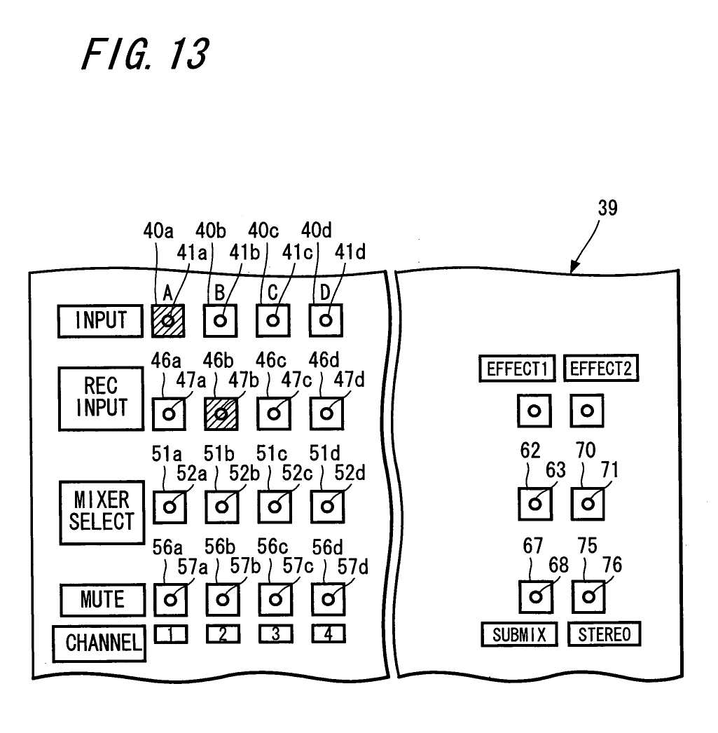

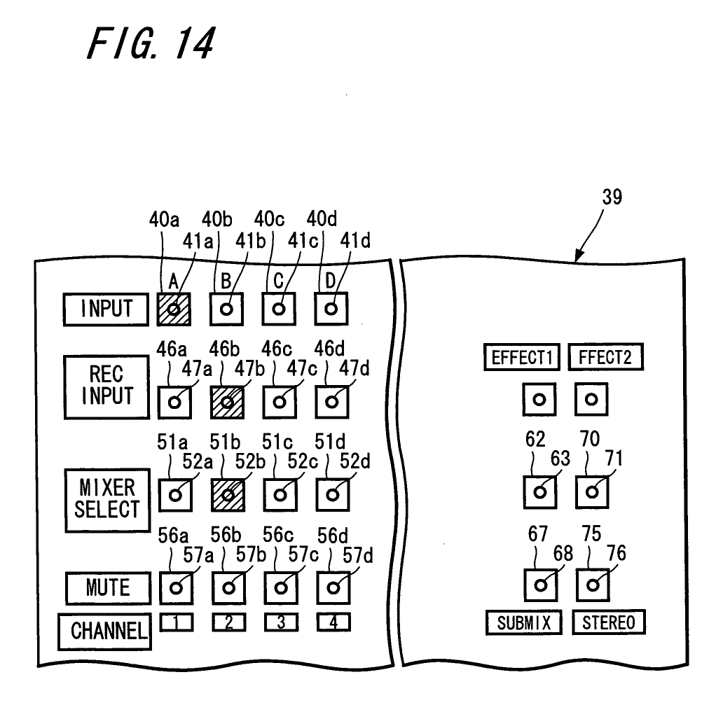

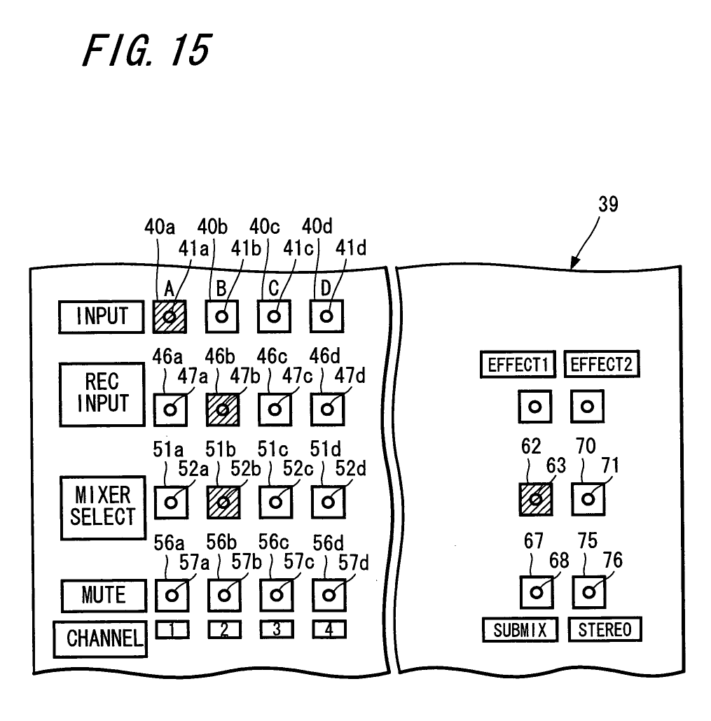

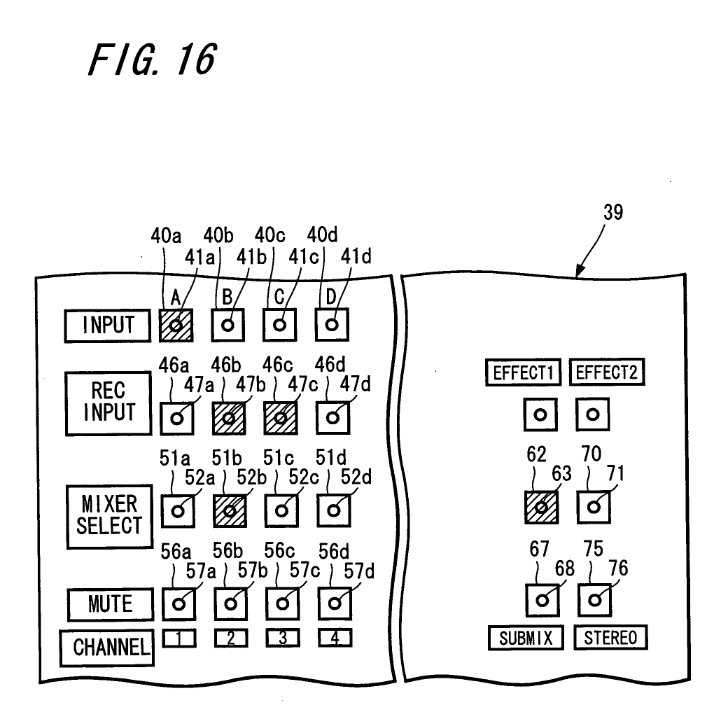

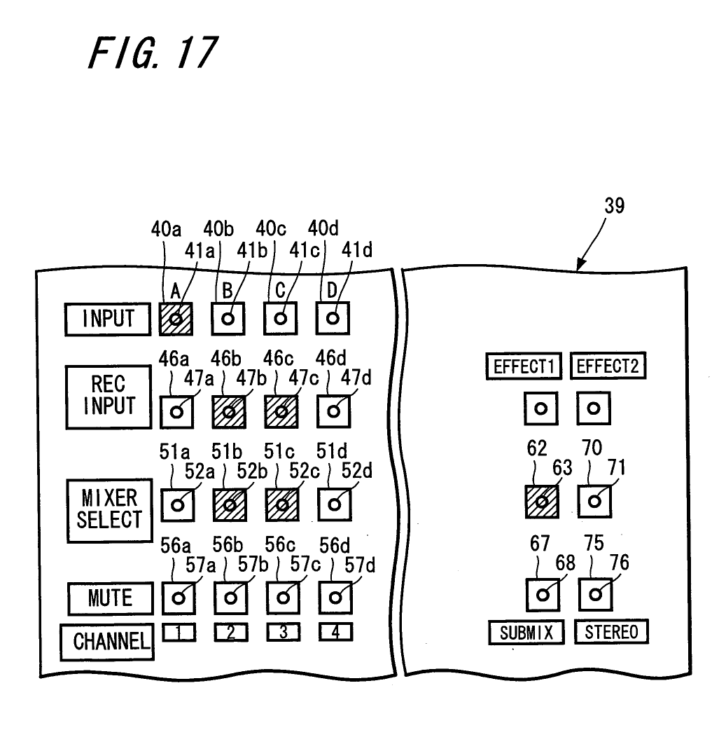

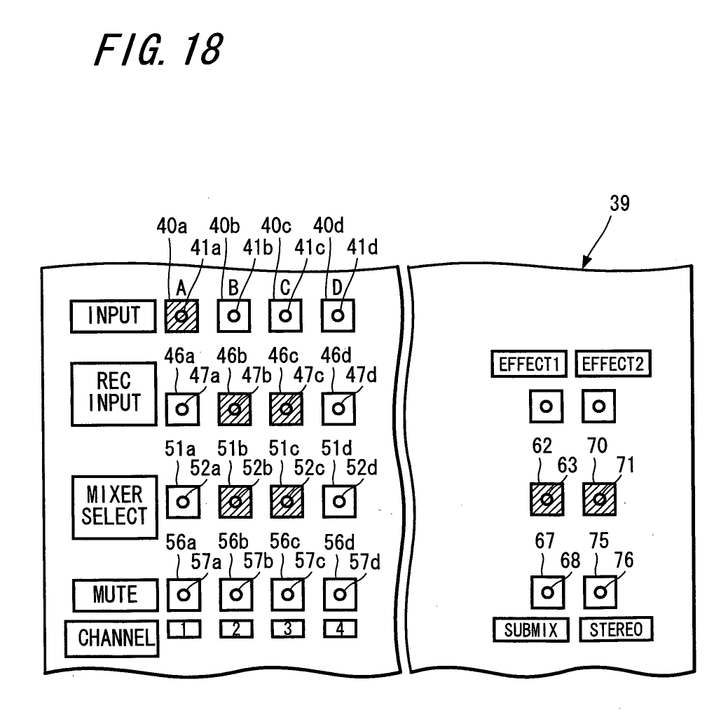

In order to display the first signal transmission path, the first input display device 41a, corresponding to the object name “INPUT-A” of the first input means 1a, is caused to light, as shown in FIG. 12. Next, after a predetermined length of time, preferably within a range of for example 0.1 second to 1 second, from the lighting of the first input display device 41a, the second recording input display device 47b, indicating input of “CHANNEL 2” representing the second channel as shown in FIG. 13, is caused to light. At this time, lighting of the first input display device 41a is continued. Next, after a predetermined length of time (0.2 seconds), and with lighting of the first input display device 41a and of the second recording input display device 47b continued, the second mixer selection display device 52b, indicating the output of the second channel, is caused to light, as shown in FIG. 14. Then, after a predetermined length of time (0.2 seconds), and with lighting of the display devices 41a, 47b and 52b continued, the submix display device 63 corresponding to “SUBMIX” is caused to light, as shown in FIG. 15. Next, after a predetermined length of time (0.2 seconds) has elapsed, and with lighting of the display devices 41a, 47b, 52b and 63 continued, the third recording input display device 47c indicating the input of “CHANNEL 3” is caused to light, as shown in FIG. 16. Then, after a predetermined length of time (0.2 seconds) has elapsed, and with lighting of the display devices 41a, 47b, 52b, 63 and 47c continued, the third mixer selection display device 52c, corresponding to the output of “CHANNEL 3”, is caused to light, as shown in FIG. 17. Next, after a predetermined length of time (0.2 seconds) has elapsed, and with lighting of the display devices 41a, 47b, 52b, 63, 47c and 52c continued, the stereo display device 71 corresponding to “STEREO” is caused to light, as shown in FIG. 18. Accordingly, lighting display of the first signal transmission path is completed.

Next, after a predetermined length of time (0.2 seconds) has elapsed, lighting of the display devices 41a, 47b, 52b, 63, 47c, 52c and 71 employed to display the first signal transmission path is halted, and display of the second signal transmission path is performed similarly to the first signal transmission path. After lighting display of the second signal transmission path has ended, lighting display of the fourth signal transmission path is similarly performed. After lighting display of the fourth signal transmission path has ended, lighting display of the first signal transmission path is again performed. This lighting display is repeated until a halt instruction is generated by ending the extended press of a button, or until the next operation to form a signal transmission path.

In the above description, lighting display of the first, second, and fourth signal transmission paths is performed in sequence; however, lighting display can be performed in the order fourth, first and second signal transmission path, or in some other arbitrary order. Further, a new display device alone can be lit for a predetermined length of time, for example from 0.2 to 2 seconds, without continuing the lighting of the previously lighted display device. For example, when displaying the first signal transmission path, the display devices 41a, 47b, 52b, 63, 47c, 52c and 71 can each be lighted in sequence for a predetermined length of time.

When in this embodiment one of the mute buttons 57a through 571, 67 and 75 is turned on as interruption instruction means while in a state in which a desired signal transmission path is formed, signal transmission in the signal transmission path including the mute button of the operation is interrupted, that is, disabled. In this mute state, if a button associated with the signal transmission path is pressed for an extended length of time, for example 0.2 seconds or longer, to instruct display of the signal transmission path, the display device corresponding to the mute button which has been operated to mute the signal transmission path is put into a lit or flashing state. For example, in a state in which the above-described first signal transmission path is formed, if the mute button 56b is turned on, the corresponding display device 57b is put into a lit or flashing state. Hence the muted state can easily be recognized.

In this embodiment, the stereo bus 23 is considered to be a part of the output means, and whether signals are efficiently output to this bus is indicated by the display device 71. However, output selection and display are not limited thereto, and for example manual operation means for specifying the first and second output means 2a and 2b, and the display device therefor, can additionally be provided.

As is clear from the above description, this embodiment has the following advantageous results.

(1) Display devices related to a signal transmission path are put into a display state in sequence with a time difference, so that a display of the signal transmission path can easily and clearly be obtained.

(2) Through the simple method of pressing for an extended length of time a button associated with a signal transmission path, the signal transmission path can be displayed, so that a display of the signal transmission path can easily be obtained without difficulty.

(3) Data for signal transmission paths is stored in the first through fourth tables 81 to 84 in RAM 21, and the data is read to search for a signal transmission path, so that an accurate display of the signal transmission path can easily be obtained.

(4) A signal transmission path is searched recursively, so that display of a plurality of signal transmission paths can easily be obtained.

(5) The display devices 40a through 40f, 47a through 471, 52a through 521, 57a through 571, 63, 68, 71, 76, 92 and 94 are regularly arranged on the operation panel 39, so that signal transmission paths can be displayed in an easily recognizable manner.

(6) A submix bus 24 is provided, so that a plurality of signal transmission paths can be formed. Further, according to the present invention a plurality of signal transmission paths can be displayed easily and in an easily recognizable manner.

(7) A muted state can be displayed easily and in an easily recognizable manner.

This invention can be utilized in digital mixers and in other similar signal processing apparatuses.

Having described preferred embodiments of the invention with reference to the accompanying drawings, it is to be understood that the invention is not limited to those precise embodiments and that various changes and modifications could be effected therein by one skilled in the art without departing from the spirit or scope of the invention as defined in the appended claims.

1. A signal processing apparatus, comprising:
at least one input means to input electrical signals;
at least one output means to output electrical signals;
signal processing and control means, connected between said input means and said output means, and having a control function of selectively forming a plurality of signal transmission paths connected between said input means and said output means, and a function of performing arbitrary signal processing of signals in said plurality of signal transmission paths;
input selection means capable of being manually operated for selectively supplying, to said signal processing and control means, signals to order the selective use by said signal processing and control means of output signals of said input means;
output selection means, capable of being manually operated, for selectively supplying, to said signal processing and control means, signals to order that output signals of said signal processing and control means be sent to said output means;
a plurality of signal transmission path selection means, capable of being manually operated, for selectively ordering the formation of said plurality of signal transmission paths;
an input display device disposed in a predetermined positional relationship with said input selection means;
an output display device, disposed in a predetermined positional relationship with said output selection means;
a plurality of signal transmission path selection display devices, disposed in predetermined positional relationships with said plurality of signal transmission path selection means; and,
display control means, connected to said input selection means, to said output selection means, to said plurality of signal transmission path selection means, to said input display device, to said output display device, and to said plurality of signal transmission path selection display devices,
which sequentially controls the display states, with time differences, of:
one or a plurality among said input display device and said plurality of signal transmission path selection display devices, and said output display device, each of which has a predetermined relation with said selected signal transmission path
in response to operation of one or a plurality among said input selection means, said output selection means, and said plurality of signal transmission path selection means, having a predetermined relationship with said selected signal transmission path, or to operation of separately provided signal transmission path display instruction means,
in a state in which at least one signal transmission path selected from among said plurality of signal transmission paths is formed.

2. The signal processing apparatus according to claim 1, further comprising:
display control means for controlling the display states of said input display device, of said output display device, and of said plurality of signal transmission path selection display devices,
in response to operation of said input selection means, of said output selection means, and of said plurality of signal transmission path selection means when selectively forming said signal transmission paths.

3. The signal processing apparatus according to claim 1, wherein
said input display device is disposed in proximity to said input selection means, said output display device is disposed in proximity to said output selection means, and said plurality of signal transmission path selection display devices are disposed in proximity to said plurality of respective signal transmission path selection means.

4. The signal processing apparatus according to claim 1, wherein
said input selection means is an input selection switch having a manual operation unit, said output selection means is an output selection switch having a manual operation unit, and said plurality of signal transmission path selection means are a plurality of signal transmission path selection switches each having a manual operation unit; and
said input display device is integrally formed with the operation unit of said input selection switch, said output display device is integrally formed with the operation unit of said output selection switch, and said plurality of signal transmission path selection display devices are integrally formed with the operation units of said plurality of respective signal transmission path selection switches.

5. The signal processing apparatus according to claim 1, further comprising:
a plurality of interruption instruction means capable of being manually operated, for instructing interruption of signal transmission by said respective signal transmission paths;
a plurality of interruption display devices provided corresponding to said plurality of interruption instruction means; and
means for performing lighting or flashing display control of said interruption display devices relating to interrupted signal transmission paths when, in a state in which said signal transmission path is selectively formed and said interruption instruction means associated with the signal transmission path is operated to cause interruption, orders are provided to sequentially control display states, with time differences, of one or a plurality selected from among said input display device, said plurality of signal transmission path selection display devices, and said output display device.

6. The signal processing apparatus according to claim 1, wherein
said input means outputs digital signals,
said signal processing control means includes a CPU,
said CPU has control functions to selectively form a plurality of signal transmission paths, and said CPU is also used by said display control means in common.

7. The signal processing apparatus according to claim 1, wherein
said signal processing control means includes:
a bus,
a plurality of memory means selectively connected to said input means in response to operation of said input selection means,
a plurality of signal processing means to perform predetermined signal processing on the output of said plurality of memory means in response to operation of said signal transmission path selection means,
a plurality of signal transmission means for transmitting the output of said plurality of signal processing means to said bus, in response to operation of said output selection means, and
means for transmitting the signals of said bus to said output means.

8. The signal processing apparatus according to claim 1, wherein
said signal processing and control means includes:
a stereo bus,
a submix bus,
a plurality of memory means,
a plurality of signal processing means for performing predetermined signal processing on the respective outputs of said plurality of memory means in response to operation of said signal transmission path selection means,
input signal transmission means for transmitting the signals of said input means to said memory means in response to operation of said input selection means,
a plurality of stereo signal transmission means for transmitting the outputs of said plurality of signal processing means to said output means via said stereo bus, in response to operation of said output selection means,
submix selection means capable of being manually operated, for selectively issuing orders to transmit signals via said submix bus,
a submix selection display device, disposed in a predetermined positional relationship with said submix selection means, and
submix signal transmission means for selectively transmitting the output of said signal processing means to said memory means via said submix bus, in response to operation of said submix selection means.

9. The signal processing apparatus according to claim 8, wherein
said signal processing and control means further includes means for selectively transmitting signals of said input means to said stereo bus, in response to operation of said input selection means.

10. The signal processing apparatus according to claim 8, wherein
said signal processing means includes means for adjusting the signal level of the output of said memory means.

11. The signal processing apparatus according to claim 8, wherein
said signal processing means is mixer means.

12. The signal processing apparatus according to claim 4, further comprising an operation panel, wherein
the operation unit of said input selection switch, the operation unit of said output selection switch, the operation units of said plurality of signal transmission path selection switches, said input display device, said output display device, and said plurality of signal transmission path selection display devices, are disposed on said operation panel.
